(19) United States
(12) Patent Application Publication
(10) Pub. No.: US 2021/0327746 A1
(43) Pub. Date: Oct. 21, 2021

(54) TRAY STRUCTURE

(71) Applicant: PlayNitride Display Co., Ltd., Miaoli County (TW)

(72) Inventors: Chi-Heng Chen, MiaoLi County (TW); Jyun-De Wu, MiaoLi County (TW); Yen-Lin Lai, MiaoLi County (TW)

(73) Assignee: PlayNitride Display Co., Ltd., MiaoLi County (TW)

(21) Appl. No.: 16/882,555

(22) Filed: May 25, 2020

(30) Foreign Application Priority Data
Apr. 21, 2020 (TW) 109113252

(51) Int. Cl. H01L 21/687; C23C 16/458; C23C 16/46; C30B 25/10; C30B 25/12

(52) U.S. Cl. CPC H01L 21/68771; C23C 16/4586; C30B 25/12; C30B 25/10; C23C 16/46

(57) ABSTRACT

A tray structure adapted to a deposition apparatus is provided. The tray structure includes a first tray and a second tray, wherein the first tray is disposed on the deposition apparatus for control of temperature and includes a first carrying portion and at least one heat-conducting structure. The first carrying portion is disposed on a top surface of the first tray. The at least one heat-conducting structure is disposed in a recess of the first carrying portion. The second tray is disposed on the first carrying portion and the at least one heat-conducting structure.

### CROSS-REFERENCE TO RELATED APPLICATION

This application claims the priority benefit of Taiwan application serial no. 109113252, filed on Apr. 21, 2020. The entirety of the above-mentioned patent application is hereby incorporated by reference herein and made a part of this specification.

### BACKGROUND OF THE INVENTION

### 1. Field of the Invention

The invention relates to a tray structure.

### 2. Description of Related Art

An environmental condition is often an important factor that affects the epitaxy growth status of devices during semiconductor epitaxy. For example, when growing devices or layer structures on a substrate, the substrate needs to have an even temperature distribution to improve production yield.

During the manufacturing process, an epitaxial tray is often used to carry an epitaxy growth substrate, and a substrate thereon is heated by a heating module of a deposition apparatus. However, the existing tray will have uneven temperature, resulting in a situation that a central region of the substrate thereon has a lower temperature.

### SUMMARY OF THE INVENTION

The invention provides a tray structure, which improves the temperature unevenness.

According to an embodiment of the invention, a tray structure adapted to be disposed on a deposition apparatus is provided. The tray structure includes a first tray and a second tray, wherein the first tray is disposed on the deposition apparatus for control of temperature by the deposition apparatus and includes a first carrying portion and at least one heat-conducting structure. The first carrying portion is disposed on a top surface of the first tray. The at least one heat-conducting structure is disposed in a recess of the first carrying portion. The second tray is disposed on the first carrying portion and the at least one heat-conducting structure.

Based on the above, the tray structure of an embodiment of the invention increases the temperature of a central region of a second tray by providing a heat-conducting structure, thereby improving the temperature evenness of a substrate carried by the second tray to improve the process yield.

### BRIEF DESCRIPTION OF THE DRAWINGS

FIG. 1A is a tray structure according to an embodiment of the invention.

FIG. 1B is a cross-sectional view taken along a dotted line II-IT when the tray structure of FIG. 1A is disposed on a deposition apparatus.

FIG. 1C is a schematic partial view of a tray structure according to an embodiment of the invention.

FIG. 2A is a schematic partial view of a tray structure according to an embodiment of the invention.

FIG. 2B is a schematic partial view of a tray structure according to an embodiment of the invention.

FIG. 3A is a schematic partial view of a tray structure according to an embodiment of the invention.

FIG. 3B is a schematic partial view of a tray structure according to an embodiment of the invention.

FIG. 4A is a tray structure according to an embodiment of the invention.

FIG. 4B is a schematic partial view of a tray structure according to an embodiment of the invention.

FIG. 4C is a schematic partial view of a tray structure according to an embodiment of the invention.

### DESCRIPTION OF THE EMBODIMENTS

For ease of understanding the concept of the invention, the invention is described below with reference to embodiments and the accompanying drawings.

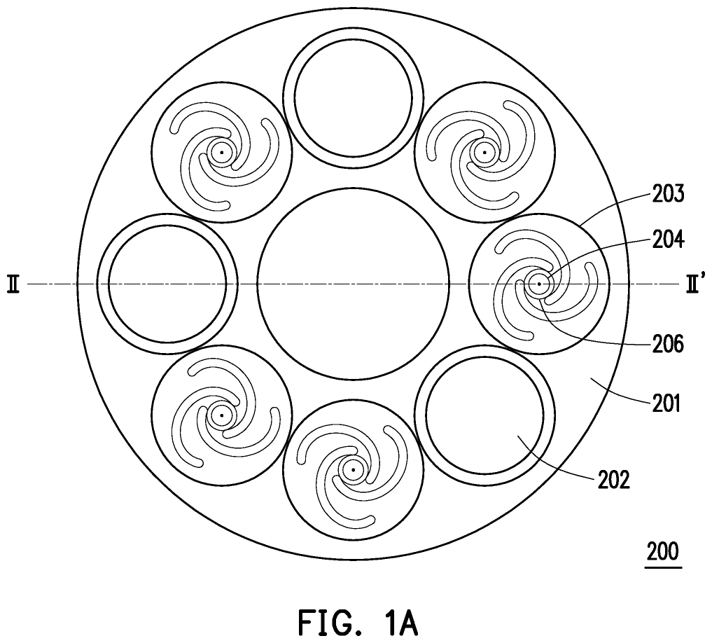

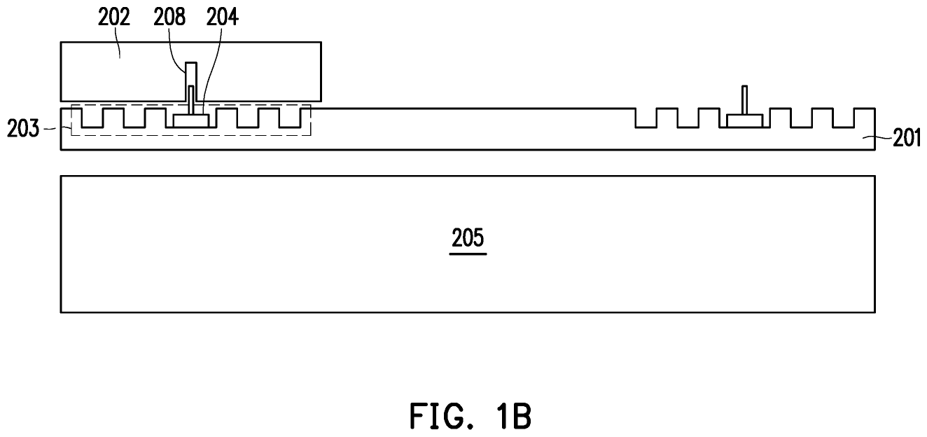

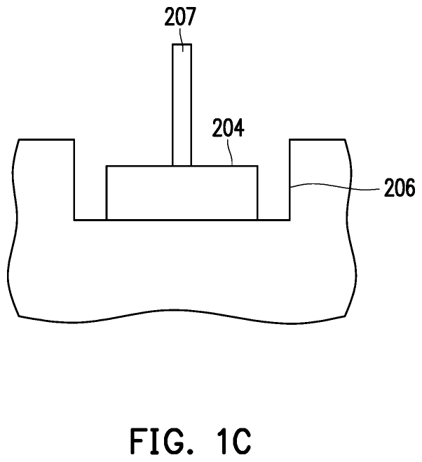

Please refer to FIGS. 1A and 1B. FIG. 1A is a tray structure according to an embodiment of the invention. FIG. 1B is a cross-sectional view taken along a dotted line II-IT when the tray structure of FIG. 1A is disposed on a deposition apparatus.

A tray structure 200 provided by the present embodiment includes a first tray 201 and a second tray 202. The first tray 201 includes a first carrying portion 203 and a heat-conducting structure 204. The first carrying portion 203 is disposed on a top surface of the first tray 201. The heat-conducting structure 204 is disposed in a recess 206 of a central region of the first carrying portion 203. The second tray 202 is disposed on the first carrying portion 203 and the heat-conducting structure 204. The tray structure 200 is adapted to be disposed on a deposition apparatus 205. Therefore, when the deposition apparatus 205 heats the first tray 201 through a heating module (not shown), the first tray 201 may heat the second tray 202, and the heat-conducting structure 204 at the recess 206 of the first carrying portion 203 of the first tray 201 further heats a central region of the second tray 202. Since the heat conductivity of the heat-conducting structure 204 is greater than or equal to the heat conductivity of the first tray 201, the central region of the second tray 202 may receive more heat energy than other regions except the central region.

According to the present embodiment, the heat conductivity of the heat-conducting structure 204 is greater than 100 W/m·K, and the heat-conducting structure may include metals such as molybdenum or tungsten, graphite or graphene.

According to the present embodiment, referring to FIGS. 1B and 1C, the heat-conducting structure 204 is disposed on a bottom surface of the recess 206. In the present embodiment, the height of the heat-conducting structure 204 is less than the depth of the recess 206, and the second tray 202 will not contact the heat-conducting structure 204. According to the present embodiment, a ratio of the depth of the recess 206 to the thickness of the first tray 201 is less than or equal to 2% and is greater than or equal to 0.1%. If the depth is too large, the temperature in the central region of the second tray 202 is insufficient, and if the depth is too small, the temperature in the central region of the second tray 202 is too high. According to the present embodiment, a ratio of the height of the heat-conducting structure 204 to a distance between the second tray 202 and the bottom surface of the recess 206 falls within a range of 0.2 to 0.8. According to the present embodiment, a distance between the second tray 202 and the heat-conducting structure 204 is greater than 0 cm and is less than or equal to 1 cm. If the distance is greater than 1 cm, the temperature in the central region of the second tray 202 is insufficient.

According to the present embodiment, the first carrying portion 203 may further include a positioning structure 207. The positioning structure 207 may be a column for positioning the second tray 202. One end of the positioning structure 207 is disposed at a center of the bottom surface of the recess 206, and another end of the positioning structure 207 abuts against the center of the second tray 202 to position the second tray 202 onto the first tray 201. Here, the second tray 202 has a central hole 208. The other end of the positioning structure 207 extends into the central hole 208 of the second tray 202 to position the second tray 202 through the positioning structure 207. Besides, the heat-conducting structure 204 is disposed symmetrically with respect to the positioning structure 207. The projected area of the heat-conducting structure 204 on the first carrying portion 203 is greater than the projected area of the positioning structure 207 on the first carrying portion 203, and the heat conductivity of the heat-conducting structure 204 is greater than or equal to the heat conductivity of the positioning structure 207, so that heat can be conducted faster and more evenly in the central region. In particular, here, the positioning structure 207 is disposed on the heat-conducting structure 204. In an embodiment not shown, the positioning structure may be disposed by passing through the heat-conducting structure, which is not limited herein.

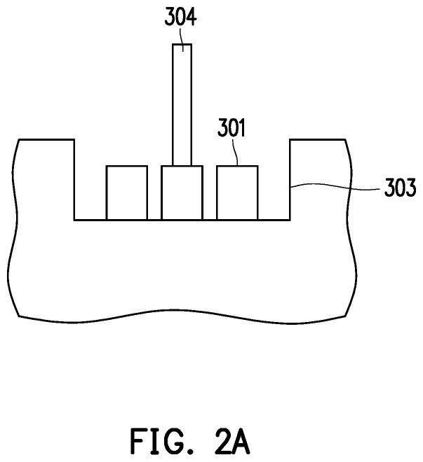

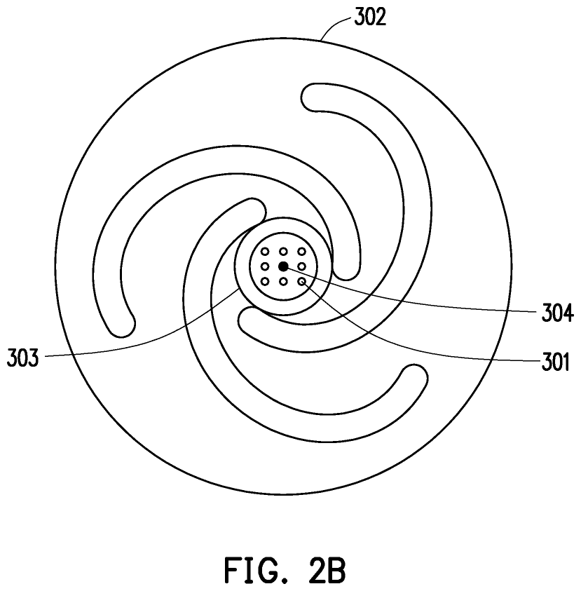

Next, please refer to FIGS. 2A and 2B. FIG. 2A is a schematic partial view of a tray structure according to another embodiment of the invention. The tray structure includes a heat-conducting structure 301. FIG. 2B is a schematic view of the heat-conducting structure 301 of FIG. 2A disposed in a central region of a first carrying portion. In order to facilitate understanding of the concept of the invention, in the following embodiments, only the parts that are different from the above embodiments shown in FIGS. 1A to 1C will be described, and the parts that are the same as or similar to the above embodiments will not be repeated.

Referring to FIGS. 2A and 2B, the heat-conducting structure 301 is a plurality of heat-conducting structures. The heat-conducting structures are arranged in an array on a bottom surface of a recess 303 of a first carrying portion 302, and are arranged symmetrically with respect to a positioning structure 304. The positioning structure 304 is disposed at a center of the recess 303. In the present embodiment, each of the plurality of heat-conducting structures is a cylinder, but the invention is not limited thereto. Each of the plurality of heat-conducting structures may be a column of any shape, optimally, a conformal shape of the second tray, so that heat can be evenly distributed on the second tray. In addition, the array form is not limited to a 3×3 rectangular array shown in FIG. 2B, but may be any n×n rectangular array, where n is a positive integer. Besides, the array form is also not limited to the rectangular array shown in FIG. 2B, but may also be a circular rectangular array and the like.

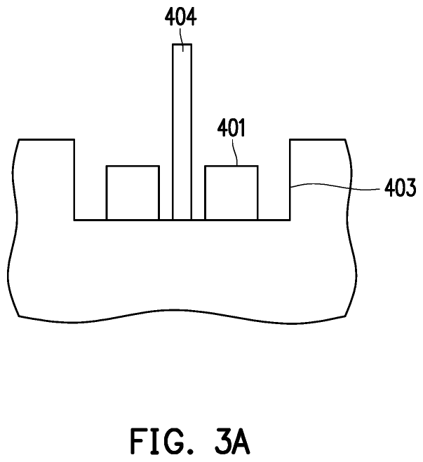

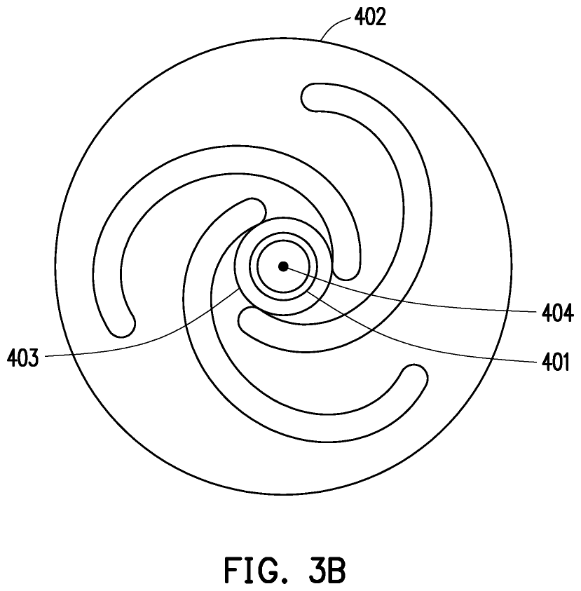

Next, please refer to FIGS. 3A and 3B. FIG. 3A is a schematic partial view of a tray structure according to another embodiment of the invention. FIG. 3B is a schematic view of a heat-conducting structure of FIG. 3A disposed in a central region of a first carrying portion.

Referring to FIGS. 3A and 3B, a heat-conducting structure 401 is a ring heat-conducting structure, which is disposed on a bottom surface of a recess 403 of a first carrying portion 402 and disposed symmetrically with respect to a positioning structure 404. In this way, when the deposition apparatus is heated, the ring structure makes the temperature in the central region more even. In an embodiment not shown, the positioning structure may be a discrete ring structure, which is not limited herein.

In the above embodiments, the height of the heat-conducting structure is less than the depth of the recess of the first carrying portion, which ensures that the second tray disposed thereon will not contact the heat-conducting structure. However, the invention is not limited thereto. The height of the heat-conducting structure may be greater than the depth of the recess of the first carrying portion. According to a preferred embodiment of the invention, a ratio of the height of the heat-conducting structure to the depth of the recess may be greater than or equal to 0.1 and less than or equal to 1.5. If the ratio is less than 0.1, the temperature in the central region of the second tray will not be high enough. If the ratio is greater than 1.5, the temperature in the central region of the second tray will be too high.

Next, a case where the height of the heat-conducting structure is greater than the depth of the recess of the first carrying portion will be explained in the following embodiments.

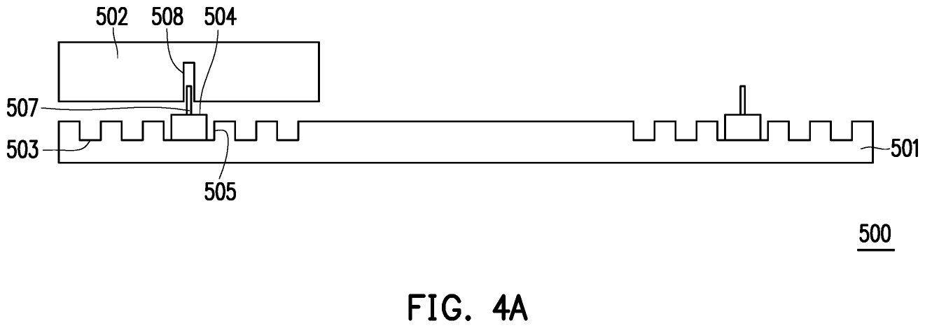

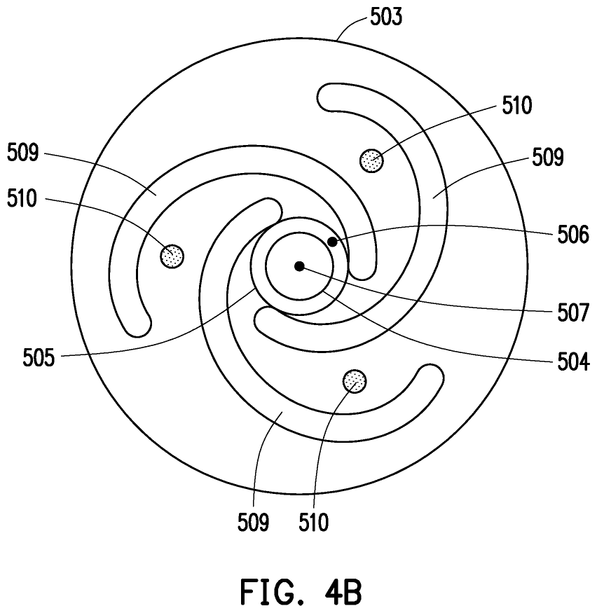

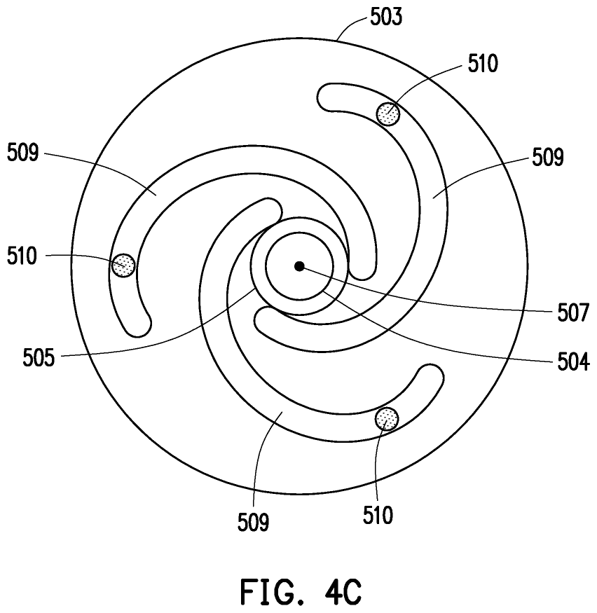

Refer to FIGS. 4A and 4B. FIG. 4A is a tray structure according to another embodiment of the invention. FIG. 4B is a first carrying portion 503 in FIG. 4A. A tray structure 500 includes a first tray 501 and a second tray 502. A first carrying portion 503 is disposed on a top surface of the first tray 501. A heat-conducting structure 504 is disposed in a recess 505 of the first carrying portion 503. One end of the positioning structure 507 is disposed at a center of the recess 505, and the other end extends into a central hole 508 of the second tray 502. The first carrying portion 503 further includes a plurality of airflow recesses 509 to adjust the temperature distribution of the second tray 502. Air is blown upward through at least one blow hole 506 located in the recess 505, so that the second tray 502 floats horizontally upward. Here, the depth of each of the plurality of airflow recesses 509 is less than or equal to the depth of the recess 505, and a ratio of the depth of each airflow recess 509 to the depth of the recess 505 is greater than or equal to 0.2, so that airflow is first evenly distributed in the recess 505 and then steadily output. The plurality of airflow recesses 509 may be disposed on the first carrying portion 503 in a rotationally symmetrical manner. In the present embodiment, although the height of the heat-conducting structure 504 is greater than the depth of the recess 505, the blow holes 506 blow air upwardly such that the second tray 502 floats horizontally upward, which also ensures that the second tray 502 does not contact the heat-conducting structure 504.

According to the present embodiment, when the blow holes 506 blow air to start the operation of the second tray 502, a ratio of a distance between the heat-conducting structure 504 and the second tray 502 to a distance between a top surface of the first carrying portion 503 and the second tray 502 falls within a range of 0.1 to 1.5. If the ratio is less than 0.1, the temperature is too high, and if the ratio is greater than 1.5, the heat distribution is not even. According to the present embodiment, a distance between the second tray 502 and the heat-conducting structure 504 is greater than 0 cm and is less than or equal to 1 cm.

According to the present embodiment, referring to FIG. 4B again, here, the first carrying portion 503 further includes a plurality of additional heat-conducting structures 510 disposed outside the recess 505 of the first carrying portion 503. Here, the additional heat-conducting structures 510 are disposed on a region other than the plurality of airflow recesses 509 of the first carrying portion 503, and the heat conductivity of each of the plurality of additional heat-conducting structures 510 is less than or equal to the heat conductivity of the heat-conducting structure 504 to reduce the temperature of the region other than the central region of the second tray 502, thereby making the temperature distribution of the second tray 502 more even.

It should be noted that although the heat-conducting structure 504 shown in FIG. 4A is a single columnar structure, the invention is not limited thereto. The heat-conducting structure 504 may be a plurality of heat-conducting structures arranged in an array, or a ring heat-conducting structure.

According to the present embodiment, on a surface perpendicular to the normal of the first tray 501, the area of the heat-conducting structure 504 is less than or equal to 5% of the area of the first tray 501, is less than or equal to 10% of the area of the first carrying portion 503, and falls within a range of 50% to 90% of the area of the recess 505. Specifically, if the area of the heat-conducting structure 504 is not large enough, the temperature in the central region of the second tray will not be high enough, and if the area of the heat-conducting structure 504 is too large, the temperature in the central region of the second tray will be too high.

Next, referring to FIG. 4C, the plurality of additional heat-conducting structures 510 of the first carrying portion 503 are disposed on a bottom surface of the plurality of airflow recesses 509. The heat conductivity of each of the plurality of additional heat-conducting structures 510 is less than or equal to the heat conductivity of the heat-conducting structure 504, so that the temperature distribution of the second tray 502 is more even.

Based on the foregoing, the tray structure of an embodiment of the invention increases the temperature of a central region of a second tray by providing a heat-conducting structure, thereby improving the temperature evenness of a substrate carried by the second tray to improve the process yield.

What is claimed is:

1. A tray structure adapted to be disposed on a deposition apparatus, the tray structure comprising:
a first tray, disposed on the deposition apparatus for control of temperature by the deposition apparatus, the first tray comprising:
a first carrying portion, disposed on a top surface of the first tray; and
at least one heat-conducting structure, disposed in a recess of the first carrying portion; and
a second tray, disposed on the first carrying portion and the at least one heat-conducting structure.

2. The tray structure according to claim 1, wherein the at least one heat-conducting structure is disposed on a bottom surface of the recess of the first carrying portion.

3. The tray structure according to claim 2, wherein a ratio of the height of the at least one heat-conducting structure to the depth of the recess is greater than or equal to 0.1 and is less than or equal to 1.5 in a normal direction of the first tray.

4. The tray structure according to claim 2, wherein the first carrying portion further comprises a positioning structure, one end of the positioning structure is disposed in a center of the first carrying portion while another end of the positioning structure abuts against a center of the second tray, and the at least one heat-conducting structure is disposed symmetrically with respect to the positioning structure.

5. The tray structure according to claim 2, wherein a distance between the second tray and the at least one heat-conducting structure is greater than 0 cm and is less than or equal to 1 cm in a normal direction of the first tray.

6. The tray structure according to claim 2, wherein a ratio of the height of the at least one heat-conducting structure to a distance between the second tray and the bottom surface of the recess falls within a range of 0.2 to 0.8 in a normal direction of the first tray.

7. The tray structure according to claim 1, wherein on a surface perpendicular to a normal direction of the first tray, an area of the at least one heat-conducting structure is less than or equal to 5% of an area of the first tray, is less than or equal to 10% of an area of the first carrying portion, and falls within a range of 50% to 90% of an area of the recess.

8. The tray structure according to claim 1, wherein the first carrying portion further comprises a plurality of airflow recesses, and the first carrying portion further comprises a plurality of additional heat-conducting structures disposed on bottom surfaces of the plurality of airflow recesses, heat conductivity of each of the plurality of additional heat-conducting structures being less than or equal to heat conductivity of the at least one heat-conducting structure.

9. The tray structure according to claim 1, wherein the first carrying portion further comprises a plurality of additional heat-conducting structures disposed outside the recess of the first carrying portion, heat conductivity of each of the plurality of additional heat-conducting structures being less than or equal to heat conductivity of the at least one heat-conducting structure.

10. The tray structure according to claim 9, wherein on a surface perpendicular to a normal direction of the first tray, a total area of the plurality of additional heat-conducting structures is less than an area of the at least one heat-conducting structure.

11. The tray structure according to claim 1, wherein the first carrying portion further comprises at least one blow hole, and when the at least one blow hole blows air, a ratio of a distance between the at least one heat-conducting structure and the second tray to a distance between a top surface of the first carrying portion and the second tray falls within a range of 0.1 to 1.5 in a normal direction of the first tray.

12. A tray structure adapted to be disposed on a deposition apparatus, the tray structure comprising:
a tray, disposed on the deposition apparatus for control of temperature by the deposition apparatus, the tray comprising:
a carrying portion, disposed on a top surface of the tray;
at least one heat-conducting structure, disposed in a central recess of the carrying portion; and
a positioning structure, disposed in the central recess of the carrying portion, the at least one heat-conducting structure being disposed symmetrically with respect to the positioning structure,
wherein a projected area of the heat-conducting structure on the carrying portion is greater than or equal to a projected area of the positioning structure on the carrying portion, and heat conductivity of the heat-conducting structure is greater than or equal to heat conductivity of the positioning structure.
